(19) United States
(12) Patent Application Publication
(10) Pub. No.: US 2021/0366696 A1
(43) Pub. Date: Nov. 25, 2021

(54) ELECTROSTATIC CHUCK, METHOD OF MANUFACTURING ELECTROSTATIC CHUCK, AND SUBSTRATE PROCESSING APPARATUS

(71) Applicant: SEMES CO., LTD., Cheonan-si (KR)

(72) Inventors: Je Hee LEE, Uijeongbu-si (KR); Sang Kee LEE, Cheonan-si (KR)

(73) Assignee: SEMES CO., LTD., Cheonan-si (KR)

(21) Appl. No.: 17/327,567

(22) Filed: May 21, 2021

(30) Foreign Application Priority Data
May 22, 2020 (KR) 10-2020-0061545

(51) Int. Cl. H01J 37/32

(52) U.S. Cl. CPC H01J 37/32724; H01L 21/67069

(57) ABSTRACT

An electrostatic chuck according to the present disclosure includes: a dielectric plate embedded with an electrode and configured to electrostatically hold a substrate; a base plate disposed below the dielectric plate; and a heating unit provided in the base plate and configured to independently heat a plurality of regions of the substrate, such that temperatures of the plurality of regions of the substrate may be independently controlled, thereby improving uniformity of the temperature of the substrate.

### CROSS-REFERENCE TO RELATED APPLICATIONS

This application claims priority under 35 U.S.C. § 119 to Korean Patent Application No. 10-2020-0061545 filed on May 22, 2020, in the Korean Intellectual Property Office, the disclosure of which is herein incorporated by reference.

### BACKGROUND

### Field

The present disclosure relates to an electrostatic chuck embedded with a heater, a method of manufacturing the electrostatic chuck, and a substrate processing apparatus including the electrostatic chuck.

### Description of the Related Art

A support member for supporting a substrate is provided in a substrate processing apparatus that processes the substrate to manufacture a semiconductor element or a display device. An electrostatic chuck refers to a support member for fixing a substrate and preventing the movement or misalignment of the substrate during substrate processing. The electrostatic chuck uses an electrostatic force to attach (chuck) or detach (de-chuck) the substrate to/from a support in a processing chamber.

The electrostatic chuck serves not only to support the substrate, but also to adjust a temperature of the substrate in accordance with processes. This is because film quality, processing types, and surface states are sensitively changed depending on a change in temperature of the substrate during the substrate processing.

In general, as illustrated in FIG. 1, the electrostatic chuck includes a base plate 300, and a dielectric plate 100 attached to an upper surface of the base plate 300 by means of a thermally insulating bonding agent 200. The dielectric plate 100 includes a heater 130 and a DC electrode 120. The electrostatic force is generated between the dielectric plate 100 and a substrate W placed on an upper surface of the dielectric plate 100 by applying a voltage to the DC electrode 120, and the electrostatic force electrostatically holds the substrate W. The heater 130 may adjust the temperature of the substrate W.

Recently, in accordance with the tendency toward fine patterns and large-scaled wafers in response to development of technologies, a processing temperature increases, and the voltage to be applied to the electrode increases to increase the electrostatic force of the electrostatic chuck.

Therefore, a bonding interface between the dielectric plate and the base plate is warped or deflected due to a difference in coefficient of thermal expansion, which may cause a problem with structural reliability. In addition, non-uniform deposition, defective etching, or a deterioration in lifespan of the electrostatic chuck may occur due to a difference in uniformity of the temperature of the surface of the substrate.

Furthermore, because the dielectric layer is generally made of ceramic, it is very difficult to manufacture a structure having a heater disposed in a ceramic dielectric material, and a large amount of cost is required to manufacture this structure.

### DOCUMENT OF RELATED ART

### Patent Document

(Patent Document 1) Korean Patent No. 10-0804842 (Feb. 12, 2008)

### SUMMARY

The present disclosure has been made in an effort to provide an electrostatic chuck, a method of manufacturing the electrostatic chuck, and a substrate processing apparatus including the electrostatic chuck, in which a heater capable of independently controlling a plurality of regions of a substrate is provided in a base plate, thereby improving uniformity of a temperature of a surface of the substrate.

The present disclosure has also been made in an effort to provide an electrostatic chuck including a heater that is easily manufactured, a method of manufacturing the electrostatic chuck, and a substrate processing apparatus including the electrostatic chuck.

The objects of the present disclosure are not limited to the above-mentioned objects, and other objects and advantages of the present disclosure, which are not mentioned above, may be clearly understood from the following descriptions.

In one aspect, the present disclosure provides an electrostatic chuck including: a dielectric plate embedded with an electrode and configured to electrostatically hold a substrate; a base plate disposed below the dielectric plate; and a heating unit provided in the base plate and configured to independently heat a plurality of regions of the substrate.

The heating unit may include: a plurality of heaters disposed to be separated from one another and configured to be independently controlled; and heat shield parts provided between the plurality of heaters.

The heat shield part may include an internal space.

The internal space may be filled with a material that may withstand a high temperature and have high thermal insulation.

Alternatively, the internal space may be filled with a gas.

Alternatively, the internal space may be in a vacuum state.

Alternatively, the heat shield part may be made of a heat shield material.

The plurality of heaters and the heat shield parts may be provided in ring shapes.

The heating unit may further include an insulating layer.

The electrostatic chuck may further include a cooling member disposed below the base plate.

In addition, the cooling member may be configured as a cooling flow path through which a cooling fluid flows.

The temperature may be easily adjusted by an interaction of the cooling member and the heating unit.

The base plate may be made of aluminum (Al).

In another aspect, the present disclosure provides a method of manufacturing an electrostatic chuck, the method including: a preparation step of providing a base plate and a dielectric plate embedded with an electrode; a heating unit forming step of forming a heating unit in the base plate; and a bonding step of bonding a lower surface of the dielectric plate and an upper surface of the base plate.

The heating unit forming step may include a step of embedding a heater in the base plate.

In this case, the heater may be a sheath heater.

Alternatively, the heating unit forming step may include a step of sequentially laminating the heating unit on the base plate.

In this case, the heating unit forming step may include a step of patterning the heater.

The heating unit may include a polyimide film heater.

In still another aspect, the present disclosure provides a substrate processing apparatus including: a process chamber configured to provide a substrate processing space; an electrostatic chuck disposed in the substrate processing space; and a plasma generator configured to generate plasma in the substrate processing space, in which the electrostatic chuck includes: a dielectric plate embedded with an electrode and configured to electrostatically hold a substrate; a base plate disposed below the dielectric plate; and a heating unit provided in the base plate and configured to independently heat a plurality of regions of the substrate, in which the heating unit includes: a plurality of heaters disposed to be separated from one another; heat shield parts provided between the plurality of heaters; and an insulating layer configured to surround the heaters, and in which a cooling member for cooling the substrate is disposed below the base plate.

The electrostatic chuck according to the present disclosure includes the heating unit provided in the base plate, and the heating unit has a plurality of heaters disposed to be separated from one another, and heat shield parts provided between the plurality of heaters, such that the plurality of regions of the substrate may be independently controlled.

In addition, according to the electrostatic chuck according to the present disclosure, the heat distribution may be easily adjusted for each region of the substrate, and as a result, it is possible to uniformly process the substrate.

In addition, the electrostatic chuck according to the present disclosure includes the heating unit provided in the base plate instead of the dielectric plate, and thus the electrostatic chuck may be easily manufactured and advantageous in terms of costs.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view illustrating a substrate processing apparatus including an electrostatic chuck in the related art;

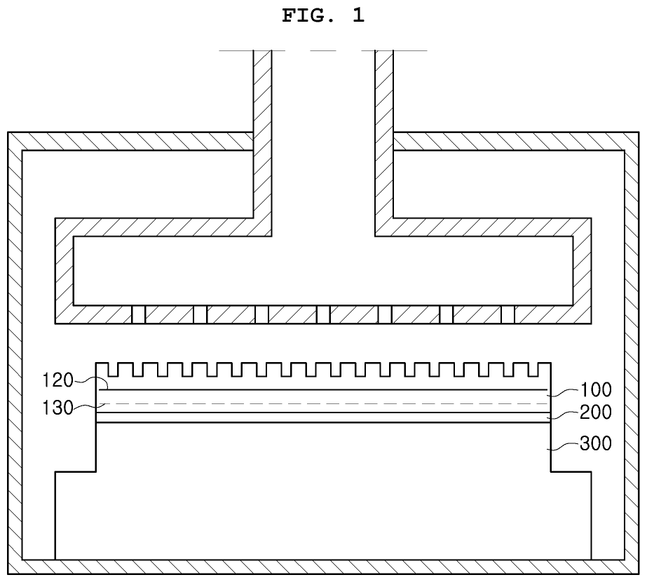

FIG. 2 is a cross-sectional view illustrating a configuration of an electrostatic chuck according to an embodiment of the present disclosure;

FIG. 3 is a top plan view of FIG. 2;

FIG. 4 is a flowchart illustrating a method of manufacturing the electrostatic chuck according to the embodiment of the present disclosure;

FIG. 5 is a cross-sectional view illustrating a process of manufacturing a heating unit according to the embodiment of the present disclosure;

FIG. 6 is a cross-sectional view illustrating a part of a configuration of the electrostatic chuck completely manufactured through the process illustrated in FIG. 5; and

FIG. 7 is a cross-sectional view illustrating a substrate processing apparatus including the electrostatic chuck according to the embodiment of the present disclosure.

### DETAILED DESCRIPTION OF THE EMBODIMENT

Hereinafter, embodiments of the present disclosure will be described in detail with reference to the accompanying drawings.

The present disclosure may be implemented in various different ways and is not limited to the embodiments described herein.

A detailed description of a part irrelevant to the subject matter of the present disclosure will be omitted to clearly describe the present disclosure, and the same or similar constituent elements will be designated by the same reference numerals throughout the specification.

In addition, unless explicitly described to the contrary, the word “comprise/include” and variations such as “comprises/includes” or “comprising/including” will be understood to imply the inclusion of stated elements, not the exclusion of any other elements. The terms used herein are merely for the purpose of describing a specific embodiment, and not intended to limit the present disclosure. Unless the terms are defined as other meanings in the present specification, the technical terms may be interpreted as meanings appreciated by those skilled in the art.

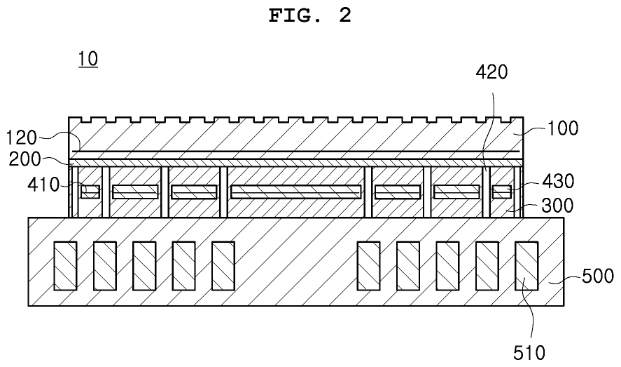

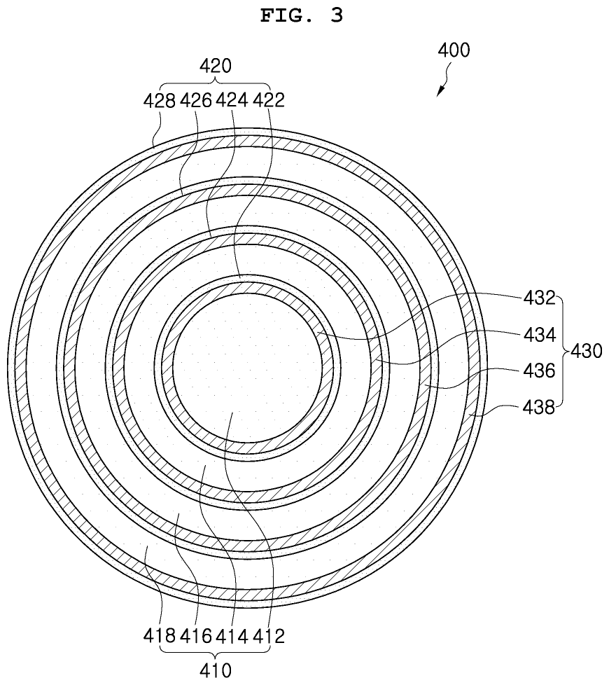

An entire configuration of an electrostatic chuck 10 according to an embodiment of the present disclosure will be described with reference to FIGS. 2 and 3.

The electrostatic chuck 10 according to the embodiment of the present disclosure has a heater having a plurality of divided sections that may be independently controlled. In addition, the electrostatic chuck 10 according to the embodiment of the present disclosure may be applied to substrate processing apparatuses for performing substrate processing such as chemical vapor deposition (CVD), sputtering, deposition, plasma etching, measurement, and inspection. However, the present disclosure is not limited to the above-mentioned processes, and the electrostatic chuck 10 may be used for apparatuses for supporting and heating substrates.

FIG. 2 is a cross-sectional view illustrating the electrostatic chuck 10 according to the embodiment of the present disclosure, and FIG. 3 is a top plan view of FIG. 2 and illustrates a configuration of a heating unit included in the electrostatic chuck 10. As illustrated in FIGS. 2 and 3, the electrostatic chuck 10 according to the embodiment of the present disclosure includes a dielectric plate 100, a base plate 300, a heating unit 400, and a body 500.

The dielectric plate 100 is positioned at an upper end of the electrostatic chuck 10, and a substrate, which is a processing object, is placed on an upper surface of the dielectric plate 100. The dielectric plate 100 is formed of a dielectric material having a circular plate shape and made of a material having dielectric properties. For example, the dielectric plate is made of ceramic. The upper surface of the dielectric plate 100 has a smaller radius than the substrate. The dielectric plate 100 may have a supply flow path (not illustrated) used as a passageway through which a heat transfer gas is supplied to a bottom surface of the substrate. The dielectric plate 100 includes an electrostatic electrode 120.

The electrostatic electrode 120 is positioned in the dielectric plate 100. The electrostatic electrode 120 is electrically connected to a separate power source (not illustrated). An electrostatic force is applied between the electrostatic electrode 120 and the substrate by electric current applied to the electrostatic electrode 120, and the substrate is attached to the dielectric plate 100 by the electrostatic force.

The base plate 300 is disposed below the dielectric plate 100. In this case, a bottom surface of the dielectric plate 100 and an upper surface of the base plate 300 are bonded by a bonding layer 200.

The base plate 300 includes the heating unit 400 configured to heat the substrate. Specifically, the heating unit 400 is embedded in the base plate 300. The heating unit 400 includes a plurality of heaters 410 disposed to be separated from one another, and heat shield parts 420 provided between the plurality of heaters 410.

As illustrated in FIG. 3, a first heater 412, a second heater 414, a third heater 416, and a fourth heater 418 may be disposed in the base plate 300. A first shield part 422 may be provided between the first heater 412 and the second heater 414, a second shield part 424 may be provided between the second heater 414 and the third heater 416, a third shield part 426 may be provided between the third heater 416 and the fourth heater 418, and a fourth shield part 428 may be provided to surround the fourth heater 418. Therefore, the heating unit 400 is divided into a first section embedded with the first heater 412, a second section embedded with the second heater 414, a third section embedded with the third heater 416, and a fourth section embedded with the fourth heater 418. The first heater 412, the second heater 414, the third heater 416, and the fourth heater 418 are connected to external connection terminals (not illustrated), respectively, and connected to a heater control unit (not illustrated), such that the first heater 412, the second heater 414, the third heater 416, and the fourth heater 418 may be independently controlled.

In this case, an effect of independently controlling the sections may deteriorate due to thermal interference and heat exchange occurring between the respective sections. In order to prevent the thermal interference and the heat exchange, the heat shield parts 420 are provided between the respective sections to thermally insulate the respective sections, thereby minimizing the thermal interference between the respective sections. As a result, it is possible to improve the effect of independently controlling the heating unit 400.

Each of the heat shield parts 420 may include an internal space. The internal space may be filled with a thermal insulation material that withstands a high temperature and has high thermal insulation. For example, each of the heat shield parts 420 may be fully filled with a gas. In this case, the gas may be air. Alternatively, each of the heat shield parts 420 may be in a vacuum state. In the case in which the first shield part 422 provided between the first heater 412 and the second heater 414 is fully filled with the gas or is in the vacuum state, the heat exchange is hardly performed between the first heater 412 and the second heater 414, and thus the respective sections are efficiently and thermally insulated. Likewise, the second shield part 424 prevents the heat exchange between the second heater 414 and the third heater 416, and the third shield part 426 prevents the heat exchange between the third heater 416 and the fourth heater 418. In addition, on the same principle, the fourth shield part 428 may prevent the heat exchange between the fourth heater 418 and the outside.

In this case, a heat shield material may be a gas, as described above, a liquid such as oil, or a solid such as resin for blocking high-temperature heat. For example, the heat shield material may include or may be formed of zirconia (ZrO₂), yttrium oxide (Y₂O₃), aluminum oxide (Al₂O₃), mica, YAG (yttrium aluminum garnet), or the like.

The internal space of each of the heat shield parts 420 is configured as a closed space, such that it is possible to prevent particles from being inadvertently introduced into the heat shield parts 420. If the particles are inadvertently introduced into the heat shield parts 420, the efficiency in thermally insulating the respective sections deteriorates. Therefore, since each of the heat shield parts 420 includes the closed space containing no particle, it is possible to prevent the deterioration in efficiency in thermally insulating the respective sections. In addition, the gas, the material, or the vacuum state implemented in the first shield part 422, the second shield part 424, the third shield part 426, and the fourth shield part 428 is uniformly maintained, such that it is possible to reduce a disparity in thermal insulation performance between the sections.

Meanwhile, each of the heat shield parts 420 may be made of the heat shield material. For example, each of the heat shield parts 420 may be configured in the form of an oxide film or the like without including the internal space, thereby preventing the heat exchange between the respective heaters 410.

That is, each of the heat shield parts 420 may be configured to have the internal space filled (charged) with the heat shield material. Alternatively, each of the heat shield parts 420 may be made of the heat shield material.

The heat shield parts 420 may inhibit thermal interference and thermal effects to the respective heaters 410 from the surrounding area, and as a result, it is possible to obtain a stable thermal insulation effect. In addition, the stable thermal insulation improves the ability to independently control the respective heaters 410.

Each of the plurality of heaters 410 constituting the heating unit 400 may use a conductor that generates Joule's heat using electric current. For example, high-melting-point metal such as tungsten (W), tantalum (Ta), molybdenum (Mo), or platinum (Pt) may be used. Alternatively, an alloy containing iron (Fe), chromium (Cr), and aluminum (Al), an alloy containing nickel (Ni) and chromium (Cr), or a nonmetal material such as SiC, molybdenum silicide, and carbon (C) may be used.

The heating unit 400 may further include an insulating layer 430. Specifically, the respective heaters 410 of the heating unit 400 may be embedded in the insulating layer 430. The insulating layer 430 is disposed to prevent the heater 410 from being electrically connected to other members. That is, the insulating layer 430 may be made of a material that sufficiently insulates the first heater 412, the second heater 414, the third heater 416, and the fourth heater 418 from other members. The insulating layer 430 may be made of aluminum oxide (Al₂O₃), aluminum nitride (AlN), silicon dioxide (Si02), silicon nitride (SiN), or the like.

As described above, a high thermal insulation effect between the first section and the second section may be obtained by the first shield part 422, a high thermal insulation effect between the second section and the third section may be obtained by the second shield part 424, a high thermal insulation effect between the third section and the fourth section may be obtained by the third shield part 426, and a high thermal insulation effect between the fourth section and the external environment may be obtained by the fourth shield part 428. Therefore, the thermal insulation effect obtained by the heat shield parts 420 may not depend on the usage environment. In addition, the stable thermal insulation may improve the ability to independently control the respective heaters 410, and thus the temperature controllability for the respective sections may be improved. As a result, it is possible to provide the heating unit 400 that may implement high in-plane temperature uniformity or intentionally provide a difference in temperature between the sections. Therefore, the temperature of each of the sections may be accurately controlled in accordance with the usage environment.

In addition, the example in which the heating unit 400 is divided into the four sections by the first heater 412, the second heater 414, the third heater 416, the fourth heater 418, the first shield part 422, the second shield part 424, the third shield part 426, and the fourth shield part 428 has been described above, but the way to divide the heating unit is not limited thereto. The number of divided sections may be optionally and appropriately set.

In addition, as illustrated in FIG. 3, the heaters and the heat shield parts 420 provided between the plurality of heaters 410 are disposed in ring shapes having different radii around a center of the base plate 300. However, the shapes of the heaters and the heat shield parts are not limited to the ring shapes. That is, the sections may be divided in various shapes. For example, the heating unit may be divided into four parts including upper, lower, left, and right parts disposed based on the center of the base plate.

The body 500 is provided below the base plate 300, and a cooling member 510 for cooling the electrostatic chuck 10 may be provided in the body 500.

Since the electrostatic chuck 10 further includes the cooling member 510, it is possible to more easily control the temperature. The cooling member 510 may be provided as a cooling flow path through which a cooling fluid flows. The cooling flow path is configured as a passageway in which the cooling fluid circulates. The cooling flow path may be connected to a separate cooling fluid supply line (not illustrated). The cooling fluid, which is cooled at a predetermined temperature and supplied from the cooling fluid supply line (not illustrated), may circulate through the cooling flow path, thereby cooling the base plate 300. When the base plate 300 is cooled, the dielectric plate 100 and the substrate are also cooled, such that the substrate is maintained at a predetermined temperature.

In this case, the interaction of the cooling member 510 for cooling the electrostatic chuck 10 and the heater 410 for heating the electrostatic chuck 10 may control the temperature of the electrostatic chuck 10. For example, a temperature of the cooling fluid flowing along the cooling flow path may be controlled, and thus the temperature of the electrostatic chuck 10 may be more easily controlled by changing the output of the heater 410 in accordance with the change in temperature of the cooling fluid.

The base plate 300 may be made of aluminum (Al), titanium (Ti), or the like. For example, the base plate 300 according to the present disclosure is made of aluminum.

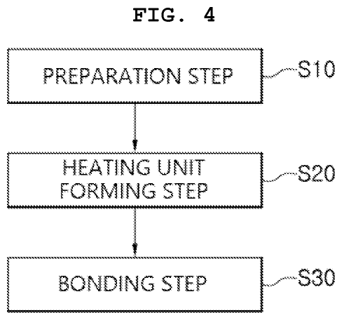

Referring to FIG. 4, a method of manufacturing the electrostatic chuck 10 includes a preparation step S10 of providing the base plate and the dielectric plate embedded with the electrode, a heating unit forming step S20 of forming the heating unit in the base plate, and a bonding step S30 of bonding the lower surface of the dielectric plate and the upper surface of the base plate.

In the preparation step S10, the base plate 300 and the dielectric plate 100 embedded with the electrode are provided in the form of circular plate shapes having the same radius. In this case, the dielectric plate 100 may be made of ceramic, and the base plate 300 may be made of aluminum.

In the heating unit forming step S20 of embedding the heating unit 400 in the base plate 300 made of aluminum, the heating unit 400 may be formed by dividing the provided base plate 300 into the plurality of regions, disposing the heaters, which each are surround by an insulator, in the regions, respectively, and providing the heat shield parts between the respective heaters.

For example, the heaters may be embedded in the base plate 300 by forming a center circle and a plurality of grooves having ring shapes having different radii in the provided base plate 300 having the circular plate shape, as illustrated in FIG. 3, alternately inserting the heaters, which each are surrounded by the insulator, and the insulating materials into the grooves, respectively, and finishing the upper side of the heaters with a metal or insulating plate having a circular plate shape. In this case, the metal plate may be made of a material identical to the material of the base plate, and the insulator and the insulating plate may be made of aluminum oxide (Al₂O₃), aluminum nitride (AlN), silica (SiO₂), silicon nitride (SiN), or the like. A sheath heater having high efficiency and excellent processability may be used as the heater embedded in the base plate 300.

In addition, the heating unit forming step S20 may include laminating the components (e.g., a plurality of heaters 412, 414, 416, and 418, a plurality of shield parts 422, 424, 426, and 428, and a plurality of insulating layers 432, 434, 436, and 438) of the heating unit 400 on the upper surface of the provided base plate 300 by sequentially coating the upper surface of the base plate 300 with the components, and covering, with the base plate 300, the upper surface on which the heating unit is formed.

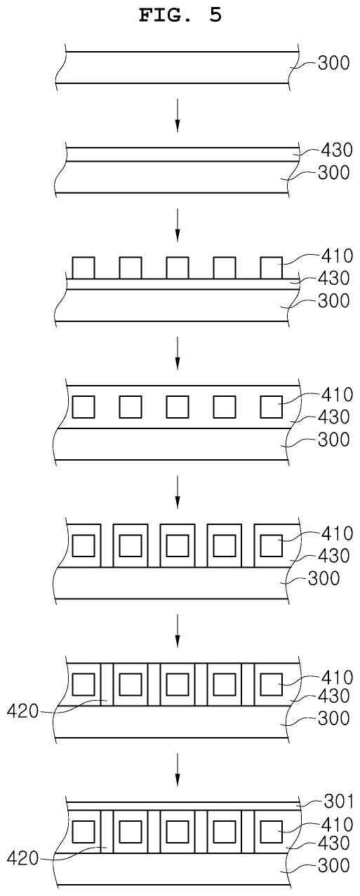

FIG. 5 is a view illustrating a process of manufacturing the heating unit 400 by laminating the components. For convenience of description, the constituent elements in the drawings are exaggerated or contracted.

First, the upper surface of the base plate 300 having the circular plate shape is coated with the insulating layer 430. The insulating layer 430 may be made of aluminum oxide (Al₂O₃), aluminum nitride (AlN), silica (SiO₂), silicon nitride (SiN), or the like. In this case, the insulating layer 430 may be formed by various methods such as physical deposition or chemical deposition. Further, the upper surface of the formed insulating layer 430 is divided into the plurality of ring-shaped regions, and the heaters 410 are patterned on the respective regions by sputtering.

The heaters 410 may include or may be formed of high-melting-point metal such as tungsten (W), tantalum (Ta), molybdenum (Mo), or platinum (Pt). Alternatively, an alloy containing iron (Fe), chromium (Cr), and aluminum (Al) or an alloy containing nickel (Ni) and chromium (Cr) may be used. As shown in FIG. 3, a plurality of heaters 412, 414, 416, and 418 may be formed by forming a heater layer on the insulating layer 430 and patterning the heater layer into the plurality of heaters 412, 414, 416, and 418.

Meanwhile, as the method of patterning the heaters 410, various methods such as printing may be used in addition to deposition such as sputtering. After the heaters 410 are patterned, the heaters 410 are coated again with the insulating layer 430, such that the upper portions of the heaters and the vacant spaces between the heaters are covered. Therefore, the plurality of heaters 410 surrounded by the insulating layer 430 is formed on the upper surface of the base plate 300.

An etching method may be used to form the heat shield parts 420 between the respective heaters 410 surrounded by the insulating layer 430. The sections between the respective heaters 410 may be assuredly separated from one another by the heat shield parts 420.

In this case, the base plate 300 need not be etched. Next, the heat shield parts 420 are formed by inserting the heat shield material into the etched regions or coating the etched regions with the heat shield material. In this case, the heat shield material may include or may be formed of zirconia (ZrO₂), yttrium oxide (Y₂O₃), aluminum oxide (Al₂O₃), mica, YAG (yttrium aluminum garnet), or the like. Alternatively, the closed space may be formed in the etched region by providing a separate cover (not illustrated), and the closed space may be filled with the gas or maintained in a vacuum state to form the heat shield parts 420.

Lastly, the upper surface on which the heating unit is completely formed is coated with a material identical to the material of the base plate 300. Alternatively, the upper surface on which the heating unit is completely formed may be finished by bonding an upper plate 301 having a circular plate shape and made of a material identical to the material of the base plate 300. As described above, it is possible to form the heating unit 400 in the base plate 300 by laminating the components of the heating unit 400 by sequentially coating the base plate 300 with the components of the heating unit 400.

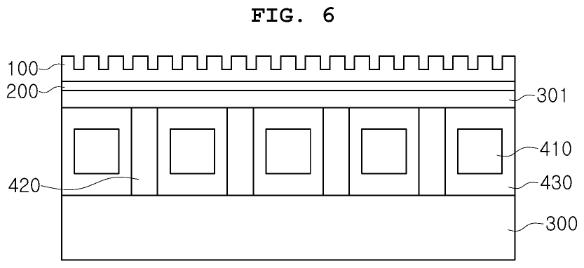

FIG. 6 is a cross-sectional view illustrating a part of the electrostatic chuck 10 completely manufactured through the bonding step after the processes illustrated in FIG. 5.

In the bonding step S30, the bonding layer 200 is formed on the lower surface of the provided dielectric plate 100 or the upper surface of the provided upper plate 301, and then the dielectric plate 100 and the upper plate 301 are bonded so that the lower surface of the dielectric plate 100 and the upper surface of the upper plate 301 face each other. In this case, the bonding layer may include or may be formed of high-temperature bonding glass, low-temperature bonding glass, or both the high-temperature bonding glass and the low-temperature bonding glass.

In addition, in the step S20 of forming the heating unit in the base plate, the heater may be a polyimide film heater.

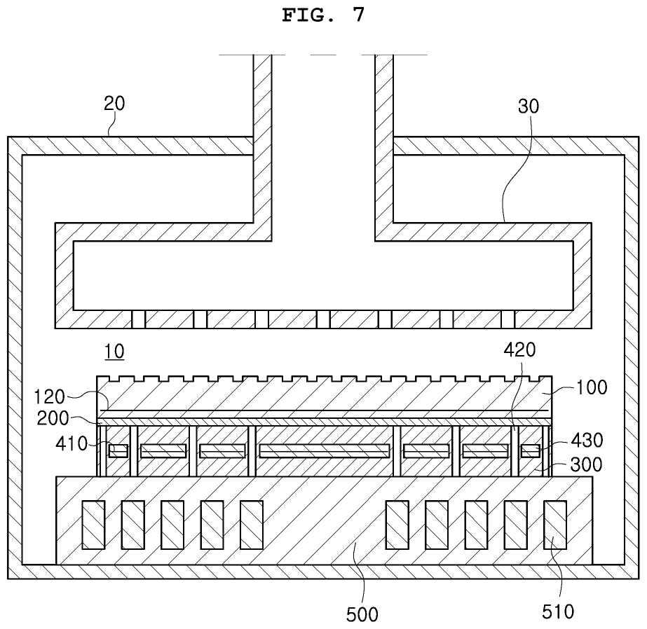

FIG. 7 is a view illustrating an example of a substrate processing apparatus including the electrostatic chuck 10 according to the embodiment of the present disclosure. The electrostatic chuck 10 according to the present disclosure may be applied to substrate processing such as chemical vapor deposition (CVD), sputtering, deposition, plasma etching, measurement, and inspection. For example, the substrate processing apparatus according to the present disclosure may be a plasma apparatus. The electrostatic chuck 10 is disposed in a process chamber 20 configured to provide a substrate processing space, and a plasma generator 30 for generating plasma in the substrate processing space is disposed above the electrostatic chuck 10. Because the configuration of the substrate processing apparatus can be sufficiently understood by those skilled in the art, a description thereof will be omitted.

As described above, the configuration in which the heaters are inserted into the base plate may be more easily implemented and advantageous in relation to costs in comparison with the configuration in which the heaters are inserted into the dielectric plate made of ceramic. In addition, the heat shield parts and the plurality of heaters, which may be independently controlled, are disposed such that that the substrate heating regions are separated. As a result, the temperature of the substrate may be controlled for each of the regions, thereby improving uniformity of the temperature of the substrate.

Those skilled in the art will understand that the present disclosure may be carried out in any other specific form without changing the technical spirit or the essential features thereof and the above-described embodiments are illustrative in all aspects and do not limit the present disclosure.

The scope of the present disclosure is represented by the claims to be described below rather than the detailed description, and it should be interpreted that the meaning and scope of the claims and all the changes or modified forms derived from the equivalent concepts thereto fall within the scope of the present disclosure.

What is claimed is:

1. An electrostatic chuck comprising:
a dielectric plate embedded with an electrode and configured to electrostatically hold a substrate;
a base plate disposed below the dielectric plate; and
a heating unit provided in the base plate and configured to independently heat a plurality of regions of the substrate.

2. The electrostatic chuck of claim 1,
wherein the heating unit comprises:
a plurality of heaters disposed to be separated from one another and configured to be independently controlled; and
a plurality of heat shield parts, each being provided in a region between corresponding two heaters of the plurality of heaters.

3. The electrostatic chuck of claim 2,
wherein each of the plurality of heat shield parts comprises an internal space.

4. The electrostatic chuck of claim 3,
wherein the internal space is filled with a heat shield material.

5. The electrostatic chuck of claim 3,
wherein the internal space is filled with a gas.

6. The electrostatic chuck of claim 3,
wherein the internal space is in a vacuum state.

7. The electrostatic chuck of claim 2,
wherein each of the plurality of heat shield parts is made of a heat shield material.

8. The electrostatic chuck of claim 2,
wherein each of the plurality of heaters is of a ring shape,
wherein each of the plurality of heat shield parts is of a ring shape, and
wherein each of the plurality of heat shield parts surrounds a corresponding one of the plurality of heaters.

9. The electrostatic chuck of claim 8,
wherein the heating unit further comprises:
a plurality of insulating layers, each being of a ring shape and being disposed between a corresponding heater of the plurality of heaters and a corresponding heat shield part of the plurality of heat shield parts.

10. The electrostatic chuck of claim 1, further comprising:
a cooling member disposed below the base plate.

11. The electrostatic chuck of claim 10,
wherein the cooling member comprises a cooling flow path through which a cooling fluid flows.

12. The electrostatic chuck of claim 11,
wherein the cooling member and the heating unit are configured to cooperatively control a temperature of the substrate.

13. The electrostatic chuck of claim 1,
wherein the base plate is made of aluminum (Al).

14. A method of manufacturing an electrostatic chuck, the method comprising:
providing a base plate and a dielectric plate embedded with an electrode;
forming a heating unit in the base plate; and
bonding a lower surface of the dielectric plate and an upper surface of the base plate to each other.

15. The method of claim 14,
wherein the forming of the heating unit comprises embedding a heater in the base plate.

16. The method of claim 15,
wherein the heater is a sheath heater.

17. The method of claim 14,
wherein the forming of the heating unit comprises laminating the heating unit on the base plate by coating the base plate with the heating unit.

18. The method of claim 17,
wherein the laminating of the heating unit comprises:
forming a heater layer; and
patterning the heater layer to form a heater.

19. The method of claim 14,
wherein the heating unit comprises a polyimide film heater.

20. A substrate processing apparatus comprising:
a process chamber having a substrate processing space;
an electrostatic chuck disposed in the substrate processing space; and
a plasma generator configured to generate plasma in the substrate processing space,
wherein the electrostatic chuck comprises:
a dielectric plate embedded with an electrode and configured to electrostatically hold a substrate;
a base plate disposed below the dielectric plate;
a cooling member configured to cool the substrate and disposed below the base plate; and
a heating unit provided in the base plate and configured to independently heat a plurality of regions of the substrate, and
wherein the heating unit comprises:
a plurality of heaters disposed to be separated from one another;
a plurality of heat shield parts, each being provided in a region between corresponding two heaters of the plurality of heaters; and
a plurality of insulating layers, each being disposed between a corresponding heater of the plurality of heaters and a corresponding heat shield part of the plurality of heat shield parts.
